(19) United States
(12) Patent Application Publication
(10) Pub. No.: US 2026/0255773 A1
(43) Pub. Date: Aug. 27, 2026

(54) ALL INORGANIC PEROVSKITES/CHALCOGENIDES MULTIJUNCTION SOLAR CELLS

(71) Applicant: Feng Yan, Chandler, AZ (US)

(72) Inventor: Feng Yan, Chandler, AZ (US)

(73) Assignee: ARIZONA BOARD OF REGENTS ON BEHALF OF ARIZONA STATE UNIVERSITY, Scottsdale, AZ (US)

(21) Appl. No.: 19/548,750

(22) Filed: Feb. 24, 2026

Related U.S. Application Data
(60) Provisional application No. 63/763,106, filed on Feb. 25, 2025.

(51) Int. Cl. H10K 30/57; H10K 30/40

(52) U.S. Cl. CPC H10K 30/57; H10K 30/40

(57) ABSTRACT

A multijunction solar cell includes a front subcell comprising an all-inorganic perovskite absorber layer comprising a cesium cation and having a first bandgap, and a transparent electrode disposed over the perovskite absorber layer. The multijunction solar cell further includes a back subcell coupled to the front subcell, the back subcell comprising a chalcogenide absorber layer comprising a cadmium-based compound or an antimony-based compound and having a second bandgap less than the first bandgap, and a bottom electrode. In some embodiments, the perovskite comprises CsPbBrₓI₃₋ₓ(x=0-3) and the chalcogenide comprises CdTe and/or Sb₂Se₃, including tandem and triple-junction configurations.

### RELATED APPLICATIONS

This application claims the benefit of U.S. Provisional Patent Application No. 63/763,106, filed Feb. 25, 2025, titled “ALL INORGANIC PEROVSKITES/CHALCOGENIDES MULTI-JUNCTION SOLAR CELLS,” the entirety of the disclosure of which is hereby incorporated herein by this reference.

### TECHNICAL FIELD

This document relates generally to materials for solar electrical power generation, and specifically to fully inorganic multijunction solar cells and devices.

### BACKGROUND

Solar cell technology is measured by power conversion efficiency (PCE), a ratio of how much solar energy is converted to usable electric energy. Hybrid organic-inorganic perovskite materials have traditionally been used in solar cell technologies due to their remarkable efficiency. However, these are susceptible to thermal and environmental degradation due to their organic compounds. For this reason, the long-term applications of hybrid organic-inorganic perovskite materials are hindered.

### SUMMARY

According to the present disclosure, a multijunction solar cell includes a front cell and a back cell arranged in a stacked configuration. The front cell includes an all-inorganic perovskite layer having a cesium cation and having a first bandgap. A first transparent layer is disposed over the perovskite layer. The back cell includes a first chalcogenide layer having a cadmium-based compound or an antimony-based compound and having a second bandgap that is less than the first bandgap. A second transparent layer is disposed over the first chalcogenide layer, and the second transparent layer is coupled to the perovskite layer. A bottom electrode is disposed on an opposite side of the device relative to the first transparent layer.

In some embodiments, the multijunction solar cell is free of organic cations. In some embodiments, the perovskite layer itself is free of organic cations. In some embodiments, the perovskite layer has a cesium lead halide perovskite having the composition CsPbBrₓI₃₋ₓ, where x ranges from 0 to 3.

In some embodiments, at least one of the first transparent layer or the second transparent layer has a sputtered indium tin oxide (ITO) film deposited while controlling an oxygen partial pressure in a range from about 1% to about 3% O₂.

In some embodiments, the first chalcogenide layer includes an antimony-based compound, and the solar cell further includes an additional cell disposed between the front cell and the back cell. The additional cell includes a second chalcogenide layer comprising a cadmium-based compound and having a third bandgap that is less than the first bandgap and greater than the second bandgap.

In some embodiments, the first chalcogenide layer includes Sb₂Se₃ and the second chalcogenide layer includes CdTe, such that the solar cell is a triple-junction stack including a top all-inorganic perovskite junction, an intermediate CdTe junction, and a bottom Sb₂Se₃ junction.

In some embodiments, the first chalcogenide layer includes CdTe. In some embodiments, the first chalcogenide layer includes Sb₂Se₃.

In some embodiments, the first transparent layer is a top electrode is a sputtered indium tin oxide (ITO) layer having a bandgap in a range from about 3.5 eV to about 3.9 eV. In some embodiments, the first transparent layer and the second transparent layer each include indium tin oxide (ITO).

In some embodiments, the front cell, the first transparent layer, and the back cell are fabricated with bandgaps selected to increase sunlight absorption. In embodiments including the additional cell, the front cell, the first transparent layer, the back cell, and the additional cell are fabricated with bandgaps selected to increase sunlight absorption.

According to the present disclosure, in some embodiments, a method of fabricating a multijunction solar cell includes forming a first transparent electrode comprising sputtered indium tin oxide (ITO). An all-inorganic perovskite absorber layer having cesium cations is formed over the first transparent electrode. A chalcogenide absorber layer is coupled to the all-inorganic perovskite absorber layer to form a multijunction solar cell having at least two junctions.

In some embodiments, forming the first transparent electrode includes sputtering indium tin oxide while adjusting an oxygen partial pressure to tune at least one of optical transmittance, optical bandgap, or sheet resistance.

In some embodiments, the all-inorganic perovskite absorber layer includes CsPbBrₓI₃₋ₓ, where x ranges from 0 to 3. In some embodiments, the chalcogenide absorber layer includes CdTe or Sb₂Se₃.

In some embodiments, the method further includes forming an additional chalcogenide absorber layer between the all-inorganic perovskite absorber layer and the chalcogenide absorber layer to form a triple-junction device. In some embodiments, the first chalcogenide layer includes Sb₂Se₃ and the second chalcogenide layer includes CdTe.

The foregoing and other aspects, features, and advantages will be apparent from the DESCRIPTION, DRAWINGS, and CLAIMS.

### BRIEF DESCRIPTION OF THE DRAWINGS

Implementations will hereinafter be described in conjunction with the appended and/or included DRAWINGS, where like designations denote like elements, and:

FIG. 1 is a schematic cross-section of an illustrative multijunction solar cell according to some embodiments.

FIG. 2 is a graphical representation of current density as a function of voltage for an all-inorganic perovskite/cadmium telluride (CdTe) multijunction solar cell.

FIG. 3 is a graphical representation of current density as a function of voltage for an all-inorganic perovskite/antimony selenide (Sb₂Se₃) multijunction solar cell.

FIG. 4 is a schematic cross-section of an illustrative multijunction solar cell according to some embodiments.

FIGS. 5A-5D are graphical plots showing material and electrode characterization data for multijunction solar cells, according to some embodiments.

### DETAILED DESCRIPTION

The following detailed description provides numerous specific details. Those skilled in the relevant arts understand that embodiments of the disclosure may be practiced without these specific details. The disclosure may also be practiced in different and alternative configurations.

Unless specifically noted, it is intended that the words and phrases in the specification and the claims be given their plain, ordinary, and accustomed meaning to those of ordinary skill in the applicable arts. The singular forms “a,” “an,” and “the” include plural referents unless the context clearly dictates otherwise. Thus, for example, a reference to “a step” includes a reference to one or more of such steps. The words “exemplary,” “example,” “embodiment,” or various forms thereof are used herein to mean serving as an example, instance, or illustration. Any aspect or feature described herein as “exemplary” or as an “example” is not necessarily to be construed as preferred or advantageous over other aspects or designs. The examples are provided solely for purposes of clarity and understanding and do not limit or restrict the disclosure. It is to be appreciated that a myriad of additional or alternate examples of varying scope could have been presented, but have been omitted for purposes of brevity.

Throughout the description and claims of this specification, the words “comprise” and “contain” and variations of the words, for example “comprising” and “comprises”, mean “including but not limited to”, and are not intended to (and do not) exclude other components.

When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

The present disclosure may be understood more readily by reference to the following detailed description taken in connection with the accompanying figures and examples, which form a part of this disclosure. It is to be understood that this disclosure is not limited to the specific materials, devices, methods, applications, conditions, or parameters described and/or shown herein, and that the terminology used herein is for the purpose of describing particular embodiments by way of example only and is not intended to be limiting of the claimed inventions. The term “plurality”, as used herein, means more than one.

As used herein, “about” or “substantially” means a percent difference less than or equal to 40% difference, 30% difference, 20% difference, 10% difference, or 5% difference.

As required, detailed embodiments are included herein. It is to be understood that the disclosed embodiments are merely exemplary of the invention that may be embodied in various forms. Therefore, specific structural and functional details disclosed herein are not to be interpreted as limits, but merely as a basis for teaching one skilled in the art to employ the present invention. The specific examples below will enable the disclosure to be better understood. However, they are given merely by way of guidance and do not imply any limitation.

Embodiments of the present disclosure relate to multijunction solar cells that are fully inorganic. Unlike conventional architectures that rely on organic-inorganic hybrid perovskites, disclosed embodiments employ fully inorganic perovskite absorbers to enable integration with inorganic chalcogenide junctions under processing conditions that would otherwise degrade organic components. In this manner, the present disclosure addresses an integration challenge associated with combining high-bandgap perovskites and lower-bandgap chalcogenides in a single multijunction solar cell.

In some embodiments, the multijunction solar cells combines an all-inorganic perovskite absorber with one or more inorganic chalcogenide absorbers to form tandem or triple-junction photovoltaic devices. In some embodiments, the disclosed multijunction solar cells are configured such that each photoactive junction has a different bandgap, thereby increasing utilization of the solar spectrum relative to single-junction devices. In some embodiments, the disclosed architecture provides improved environmental and thermal stability by eliminating organic cations from the perovskite absorber while maintaining tunable optoelectronic properties.

In semiconductor materials used for photovoltaic devices, the term “bandgap” refers to the energy difference between a valence band, in which electrons are normally bound, and a conduction band, in which electrons are free to move and contribute to electrical current. When a photon having energy equal to or greater than the bandgap is absorbed by a semiconductor, an electron may be excited from the valence band to the conduction band, thereby generating a charge carrier pair that can be collected as electrical current. Photons having energies below the bandgap are not absorbed and pass through the material, while photons having energies greater than the bandgap are absorbed but may lose excess energy as heat. Accordingly, the bandgap of a photovoltaic absorber material determines which portions of the solar spectrum are absorbed and directly influences the achievable voltage and efficiency of the solar cell.

Embodiments disclosed herein improve perovskite solar cell usability by replacing the organic matter in the perovskite with inorganic matter and use layered materials with varying bandgaps to gain more power.

To address the stability and environmental sensitivity of perovskite solar cells (PSCs), the perovskites disclosed herein may be fabricated by substituting the organic cations (e.g., methylammonium and formamidinium) in traditional organic and inorganic perovskites with inorganic cations, such as, for example, Cs+. With the organic material removed, the long-term photo-and thermal-stability of perovskite solar cells (PSCs) may be enhanced by forming the PSCs as all-inorganic perovskites (AI-PSCs) which are free from organic cations, resulting in superior thermal and chemical stability and making them more durable under real-world conditions. AI-PSCs provide a number of advantages, including enhanced stability, as they are less sensitive to moisture, heat, and UV exposure compared to hybrid organic/inorganic counterparts, providing prolonged operational lifespans.

The bandgap of AI-PSCs may be varied or “tuned” by varying the halide composition within the perovskite layer. Using this technique, AI-PSCs may be adapted to a broad array of diverse applications. Additionally, the tunable bandgap of AI-PSCs allows for optimization of light absorption. This tunable bandgap is particularly advantageous for tandem solar cells, where AI-PSCs may be paired with silicon to surpass the efficiency of single-junction devices.

Chalcogenide materials, such as Cadmium Tellurides (CdTe), are also used in solar cells. CdTe has a bandgap of about 1.5 eV and can achieve a PCE of 23%. However, the toxicity of Cd, and the limited availability or scarcity of Te significantly limits its large-scale manufacturing as compared to traditional silicon solar cell technology. Further, CdTe faces significant challenges to further improve device performance. Therefore, use of CdTe, at large scale, is limited.

Antimony chalcogenides have recently emerged as promising materials for solar cell technology, having significantly improved device performance from 5% to 11% PCE, and a tunable bandgap from 1.1 eV to 1.7 eV. However, chalcogenide materials, similar to perovskite materials, suffer from low power conversion efficiencies, thus limiting their device performance.

To address the limited power conversion efficiency of single-junction perovskite and chalcogenide solar cells, some embodiments disclosed herein combine a wide-bandgap, all-inorganic perovskite absorber with one or more chalcogenide absorbers having middle or narrower bandgaps to form tandem or multijunction solar cells with bandgaps engineered to maximize solar spectrum utilization. In some embodiments, the chalcogenide absorbers have bandgaps lower than that of the perovskite absorber, and in some embodiments the bandgaps partially overlap. The absorber layers are stacked such that higher-bandgap materials absorb higher-energy photons and lower-bandgap materials absorb lower-energy photons transmitted through the upper layers, thereby improving overall spectral utilization. The bandgaps of the absorbers may be intrinsic or compositionally tuned, for example by adjusting halide content in the perovskite absorber or elemental composition in the chalcogenide absorber, enabling selection of bandgaps suitable for tandem or triple-junction photovoltaic architectures. some embodiments, the halide selected for the perovskite may comprise Br, I and combinations thereof.

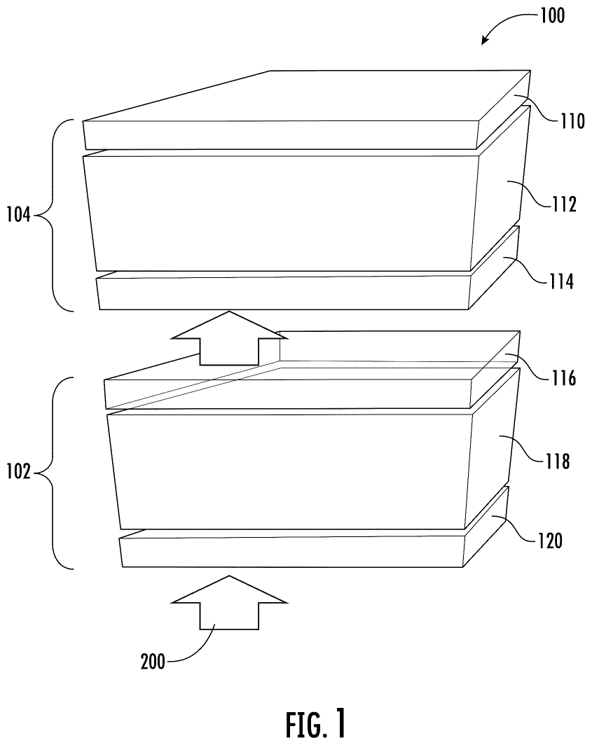

Embodiments of the present disclosure will now be described with reference to figures. FIG. 1 shows a schematic of a multijunction solar cell 100, according to some embodiments. Multijunction solar cell 100 includes a front cell 102 arranged to receive incident light 200 and a back cell 104. With its two cells 102, 104, multijunction solar cell 100 can be described as a tandem junction solar cell.

Front cell 102 may include an electrode 120 disposed on a light incident side multijunction solar cell 100. In some embodiments, electrode 120 is transparent or semi-transparent and comprises a transparent conductive material, such as indium tin oxide, thereby permitting light to enter the underlying absorber layers. In some embodiments, electrode 120 is the top electrode of the multijunction solar cell 100 and is opposite a bottom electrode 110. An perovskite absorber layer 118 is disposed on electrode 120. Perovskite absorber layer 118 forms the photoactive layer of the front cell.

In some embodiments, perovskite absorber layer 118 is a AI-PSC, as discussed above. In some embodiments, perovskite absorber layer 118 may comprise a cesium cation, further comprising at least one halide. In some embodiments, perovskite absorber layer 118 does not include organic matter. A transparent indium tin oxide ITO 116 may act as an electrode and may be disposed on perovskite absorber layer 118. In some embodiments, transparent indium tin oxide ITO 116 or transparent layer 114 may have ITO introduced using a sputtering process. Transparent indium tin oxide ITO 116 is disposed between front cell 102 and back cell 104 and electrically couples perovskite absorber layer 118 and a second electron transport layer 112.

Second electron transport layer 112 may be formed of a cadmium or an antimony-based compound, such as antimony selenide (Sb2Se3) or antimony sulfur selenide (Sb₂(S, Se)₃ ). Cadmium-based compounds may include CdTe having a bandgap of about 1.4 to 1.5 eV. Antimony-based compounds may include Sb₂(S, Se)₃ or Sb₂Se₃ having a second bandgap of about 1.1 eV.

An electrode 110 is disposed on electron transport layer 112. Electrodes may be selected to provide selective charge extraction and to reduce recombination losses.

In some embodiments, perovskite absorber layer 118 layer may comprise CsPbBrₓI₃₋ₓ, where x ranges from 0 to 3. Perovskite absorber layer 118 may comprise a tunable, first bandgap which, in some embodiments, ranges from about 1.5 to about 2.3 eV. The tunable bandgap of the disclosed inorganic perovskites (from about 1.5 to about 2.3 eV) allows for optimization of light absorption by varying the halide composition, making them highly adaptable to diverse applications. In further embodiments, perovskite absorber layer 118 may have a first bandgap of from about 1.7 eV to about 2.3 eV. In some embodiments, electrode 120 has a bandgap in a range from about 3.5 eV to about 3.9 eV, thereby minimizing parasitic absorption in the visible portion of the solar spectrum.

The selection and ordering of fully inorganic transport and absorber layers in the multijunction architecture of FIG. 1 enables two-terminal operation while maintaining charge selectivity and recombination control across heterogeneous material interfaces. In contrast to prior multijunction devices that rely on organic transport layers, the disclosed architecture permits use of transparent conductive oxides and high-energy deposition processes without compromising device stability or interface integrity.

In some embodiments, partial overlap between the bandgap of the perovskite absorber and that of an underlying chalcogenide absorber is intentionally permitted to improve current matching and recombination tolerance across series-connected junctions. Such overlap runs counter to conventional tandem design approaches that seek strict spectral partitioning, and enables robust multijunction performance in fully inorganic device stacks.

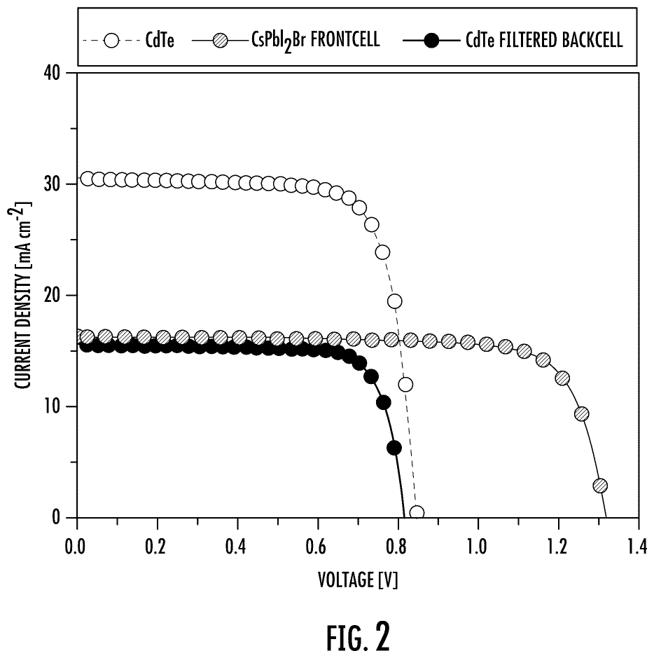

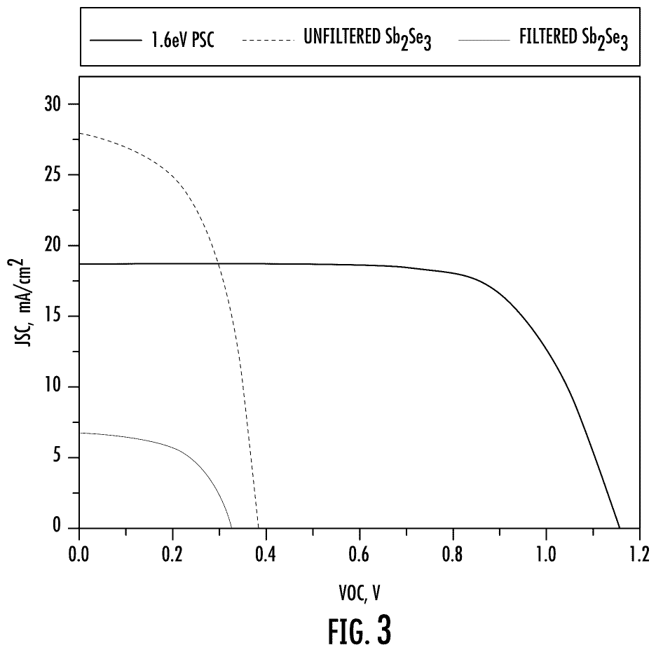

FIG. 2 depicts Jsc (short circuit current density) versus Voc (open circuit voltage) for a cell having an all-inorganic perovskite CsPbBrₓI_{3-x(x=0 to 3)}/CdTe tandem cells. FIG. 3 depicts Jsc (short circuit current density) versus Voc (open circuit voltage) for a cell having an all-inorganic perovskite CsPbBrₓI_{3-x(x=0 to 3)}/Sb₂Se₃ tandem cell.

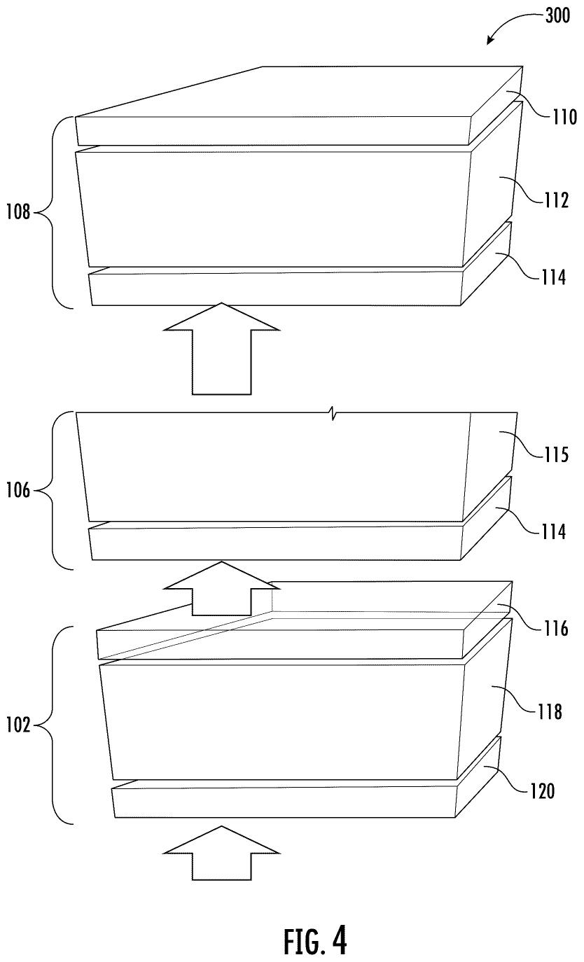

FIG. 4 illustrates a triple-junction solar cell 300 according to some embodiments. In the illustrated configuration, a first cell 102 is disposed above a second cell 106 and a third cell 108, which together form a back-cell structure. A third electron transport layer 115 forms the electrical core of the second cell 106.

In some embodiments, the perovskite absorber layer 118 comprises an all-inorganic perovskite solar cell (AI-PSC), the third electron transport layer 115 comprises CdTe, and the electron transport layer 112 comprises Sb₂Se₃. Triple-junction solar cell 300 may further include one or more transparent interconnection layers 114 disposed between adjacent junctions to provide series electrical coupling. Incident light 200 enters the device from the top and is sequentially absorbed by the top, intermediate, and bottom absorber layers.

The specific ordering of absorber materials in the triple-junction configuration of FIG. 4 is not arbitrary, but is selected to balance voltage addition, current matching, and interfacial stability across three fully inorganic junctions.

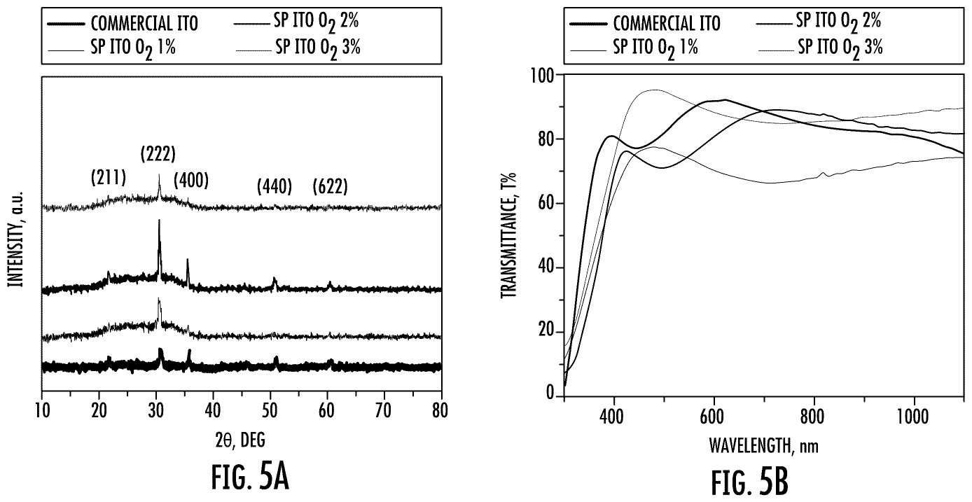

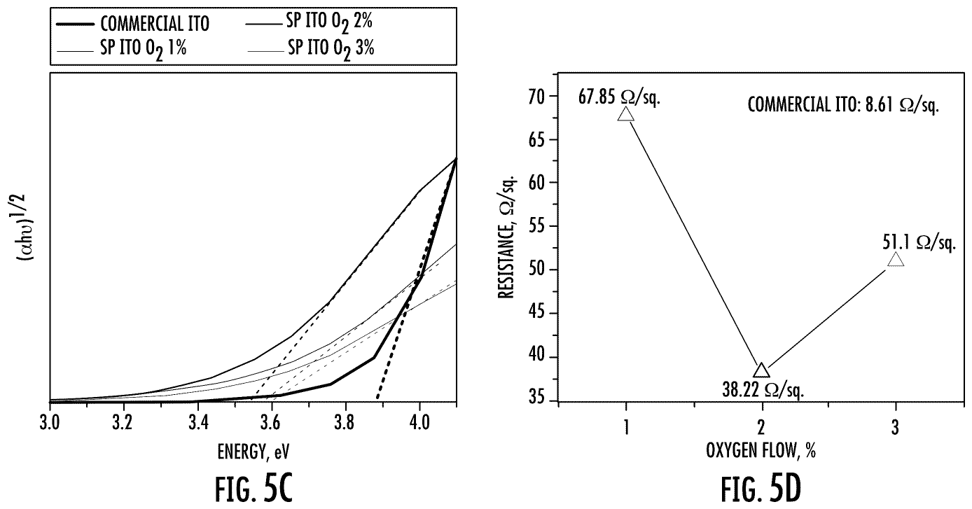

FIGS. 5A-5D shows characterization results for the top electrode of a sputtered ITO for a perovskite/CdTe multilayer device as disclosed herein. Each device is prepared under various conditions to generate the top electrode. The preparation varies the oxygen partial pressure from 1% to 3% O₂ during film formation. The graphs of FIGS. 5A-5D include X-ray diffraction data, optical transmittance spectra, optical bandgap measurements, and sheet resistivity measurements for sputtered indium tin oxide films deposited under different oxygen partial pressures.

While transparent conductive oxides are known in isolation, the present disclosure shows that tuning oxygen partial pressure during ITO deposition has a non-trivial impact on interconnection and recombination behavior in series-connected multijunction devices. In fully inorganic tandem and triple-junction architectures, small variations in optical bandgap or resistivity of the transparent layers can materially affect charge recombination and current continuity between adjacent junctions.

The data demonstrates that the transparent conductive layers used as electrodes or interconnection layers can be tuned to achieve optical transparency and electrical conductivity suitable for multijunction solar cell operation. Using the disclosed all-inorganic perovskite solar cells as disclosed herein, the long-term stability may be improved. As compared to single junction solar cells from similar materials, the efficiency may be upwards of 30%.

The present disclosure provides fully inorganic multijunction solar cell architectures that simultaneously address efficiency, stability, and manufacturability challenges associated with tandem and triple-junction devices. By combining all-inorganic perovskite absorbers with chalcogenide absorbers and transparent conductive interconnections, the disclosed devices achieve spectral utilization and long-term stability not attainable using conventional organic-inorganic hybrid systems.

Furthermore, the manufacturing process for the disclosed all-inorganic perovskite solar cells is compatible with current industrial practices. Fabrication may be integrated into existing solar cell manufacturing systems which use thin film deposition methods. By advancing the capabilities of multijunction solar cells, embodiments of the present disclosure reduce the cost per watt of solar energy and accelerate the adoption of solar power on a global scale.

More specifically, this disclosure, its aspects and embodiments, are not limited to the specific material types, components, methods, or other examples disclosed herein. Many additional material types, components, methods, and procedures known in the art are contemplated for use with particular implementations from this disclosure. Accordingly, for example, although particular implementations are disclosed, such implementations and implementing components may comprise any components, models, types, materials, versions, quantities, and/or the like as is known in the art for such systems and implementing components, consistent with the intended operation.

Many additional implementations are possible. Further implementations are within the CLAIMS.

It will be understood that implementations of the preceding disclosure include but are not limited to the specific components disclosed herein, as virtually any components consistent with the intended operation may be utilized. Accordingly, for example, it should be understood that, while the drawings and accompanying text show and describe particular implementations, any such implementation may comprise any shape, size, style, type, model, version, class, grade, measurement, concentration, material, weight, quantity, and/or the like consistent with the intended operation.

The concepts disclosed herein are not limited to the specific embodiments shown herein. For example, it is specifically contemplated that the components included in particular embodiments may be formed of any of many different types of materials or combinations that can readily be formed into shaped objects and that are consistent with the intended operation of the disclosure. For example, the components may be formed of: rubbers (synthetic and/or natural) and/or other like materials; glasses (such as fiberglass), carbon-fiber, aramid-fiber, any combination therefore, and/or other like materials; elastomers and/or other like materials; polymers such as thermoplastics (such as ABS, fluoropolymers, polyacetal, polyamide, polycarbonate, polyethylene, polysulfone, and/or the like, thermosets (such as epoxy, phenolic resin, polyimide, polyurethane, and/or the like), and/or other like materials; plastics and/or other like materials; composites and/or other like materials; metals, such as zinc, magnesium, titanium, copper, iron, steel, carbon steel, alloy steel, tool steel, stainless steel, spring steel, aluminum, and/or other like materials; and/or any combination of the foregoing.

Furthermore, embodiments of the present disclosure may be manufactured separately and then assembled together, or any or all of the components may be manufactured simultaneously and integrally joined with one another. Manufacture of these components separately or simultaneously, as understood by those of ordinary skill in the art, may involve 3-D printing, extrusion, pultrusion, vacuum forming, injection molding, blow molding, resin transfer molding, casting, forging, cold rolling, milling, drilling, reaming, turning, grinding, stamping, cutting, bending, welding, soldering, hardening, riveting, punching, plating, and/or the like. If any of the components are manufactured separately, they may then be coupled or removably coupled with one another in any manner, such as with adhesive, a weld, a fastener, any combination thereof, and/or the like for example, depending on, among other considerations, the particular material(s) forming the components.

In places where the description above refers to particular implementations, it should be readily apparent that a number of modifications may be made without departing from the spirit thereof and that these implementations may be applied to other implementations disclosed or undisclosed. The presently disclosed are, therefore, to be considered in all respects as illustrative and not restrictive.

What is claimed is:

1. A multijunction solar cell, comprising:
a front cell comprising an all-inorganic, perovskite layer comprising a cesium cation and having a first bandgap, and a first transparent layer disposed over the perovskite layer;
a back cell comprising a first chalcogenide layer comprising a cadmium-based compound or an antimony-based compound, and having a second bandgap which is less than the first bandgap, and a second transparent layer disposed over the first chalcogenide layer, wherein the second transparent layer is coupled to the perovskite layer, and
a bottom electrode.

2. The solar cell of claim 1, wherein the solar cell is free of organic cations.

3. The solar cell of claim 2, wherein the perovskite layer is free of organic cations.

4. The solar cell of claim 1, wherein the perovskite layer comprises CsPbBrₓI₃₋ₓ and x ranges from 0 to 3.

5. The solar cell of claim 1, wherein at least one of the first transparent layer or the second transparent layer comprises a sputtered indium tin oxide (ITO) film deposited while controlling an oxygen partial pressure in a range from about 1% to about 3% O₂.

6. The solar cell of claim 1, wherein the first chalcogenide layer comprises the antimony-based compound, the solar cell further comprising an additional cell disposed between the back cell and the front cell, the additional cell comprising a second chalcogenide layer comprising a cadmium-based compound, wherein the second chalcogenide layer comprises a third bandgap which is less than the first bandgap and greater than the second bandgap.

7. The solar cell of claim 6, wherein the first chalcogenide layer comprises Sb2Se3, and the second chalcogenide layer comprises CdTe, such that the device comprises a triple-junction stack including a top all-inorganic perovskite junction, an intermediate CdTe junction, and a bottom Sb2Se3 junction.

8. The solar cell of claim 1, wherein the first chalcogenide layer comprises CdTe.

9. The solar cell of claim 1, wherein the first chalcogenide layer comprises Sb₂Se₃.

10. The solar cell of claim 1, wherein the first transparent layer is a top electrode comprising a sputtered indium tin oxide (ITO) layer having a bandgap of from about 3.5 to about 3.9 eV.

11. The solar cell of claim 1, wherein the first and second transparent layers comprise indium tin oxide (ITO).

12. The solar cell of claim 1, wherein the front cell, first transparent layer, and back cell are fabricated with suitable bandgaps to increase sunlight absorption.

13. The solar cell of claim 6, wherein the front cell, first transparent layer, back cell and additional cell are fabricated with suitable bandgaps to increase sunlight absorption.

14. A method of fabricating a multijunction solar cell, comprising:
forming a first transparent electrode comprising sputtered ITO;
forming an all-inorganic perovskite absorber layer comprising a cesium cation over the first transparent electrode; and
coupling a chalcogenide absorber layer to the all-inorganic perovskite absorber layer to form a multijunction solar cell.

15. The method of claim 14, wherein forming the first transparent electrode comprises sputtering ITO while adjusting an oxygen partial pressure to tune at least one of optical transmittance, bandgap, or sheet resistance.

16. The method of claim 14, wherein the all-inorganic perovskite absorber layer comprises CsPbBrₓI₃₋ₓ, where x ranges from 0 to 3.

17. The method of claim 14, wherein the chalcogenide absorber layer comprises CdTe or Sb₂Se₃.

18. The method of claim 14, further comprising forming an additional chalcogenide absorber layer between the all-inorganic perovskite absorber layer and the chalcogenide absorber layer to form a triple-junction device.

19. The method of claim 14, wherein forming at least one transparent electrode comprises sputtering indium tin oxide (ITO) while controlling an oxygen partial pressure in a range from about 1% to about 3% O₂.

20. The method of claim 18, wherein the first chalcogenide layer comprises Sb₂Se₃, and the second chalcogenide layer comprises CdTe.
